(19) United States
(12) Patent Application Publication
(10) Pub. No.: US 2026/0018493 A1
(43) Pub. Date: Jan. 15, 2026

(54) SEMICONDUCTOR STRUCTURE

(71) Applicant: Powerchip Semiconductor Manufacturing Corporation, Hsinchu (TW)

(72) Inventors: Pei-Rong Ni, Hsinchu (TW); Chun-Lin Lu, Hsinchu City (TW); Chih-Hao Chuang, Hsinchu City (TW)

(73) Assignee: Powerchip Semiconductor Manufacturing Corporation, Hsinchu (TW)

(21) Appl. No.: 18/977,862

(22) Filed: Dec. 11, 2024

(30) Foreign Application Priority Data
Jul. 11, 2024 (TW) 113126011

(51) Int. Cl. H01L 23/48; H01L 23/00; H01L 23/528; H01L 25/07

(52) U.S. Cl. CPC H01L 23/481; H01L 23/528; H01L 24/32; H01L 25/074; H01L 24/05; H01L 24/29; H01L 2224/05025; H01L 2224/29082; H01L 2224/32145; H01L 2225/06544; H01L 2225/06565

(57) ABSTRACT

A semiconductor structure includes a plurality of first wafers and a through-substrate via (TSV). The plurality of first wafers include a plurality of conductive connection lines. Each of the conductive connection lines is located in the corresponding first wafer. The through-substrate via passes through the plurality of first wafers and a plurality of end portions of the plurality of conductive connection lines. The plurality of end portions are embedded in the through-substrate via.

### CROSS-REFERENCE TO RELATED APPLICATION

This application claims the priority benefit of Taiwan application serial no. 113126011, filed on Jul. 11, 2024. The entirety of the above-mentioned patent application is hereby incorporated by reference herein and made a part of this specification.

### BACKGROUND

### Technical Field

The disclosure relates to a semiconductor structure, and particularly relates to a semiconductor structure including a through-substrate via (TSV).

### Description of Related Art

Currently, a plurality of wafers are electrically connected to each other through a through-substrate via and a metal ring in the wafer. Since the through-substrate via passes through the metal ring, and the metal ring needs to contact the through-substrate via, the size of the through-substrate via should be larger than the size of the metal ring. However, during the dry etching process for forming the through-substrate via, the hard mask phenomenon of the metal ring will cause the size of the bottom of the through-substrate via to be reduced, thus easily causing an open circuit problem.

### SUMMARY

The disclosure provides a semiconductor structure that may prevent an open circuit between a plurality of wafers, thereby preventing the failure of the semiconductor structure.

The disclosure provides a semiconductor structure, including a plurality of first wafers and a through-substrate via. The plurality of first wafers include a plurality of conductive connection lines. Each of the conductive connection lines is located in the corresponding first wafer. The through-substrate via passes through the plurality of first wafers and a plurality of end portions of the plurality of conductive connection lines. The plurality of end portions are embedded in the through-substrate via.

According to an embodiment of the disclosure, in the semiconductor structure, the plurality of end portions may include a plurality of annular portions and a plurality of pin portions. Each of the annular portions may have an opening. Each of the pin portions is connected to the corresponding annular portion and protrudes toward an inside of the corresponding opening. A plurality of top-view patterns of the plurality of pin portions may not overlap each other.

According to an embodiment of the disclosure, in the semiconductor structure, the through-substrate via may pass through a plurality of openings.

According to an embodiment of the disclosure, in the semiconductor structure, the plurality of pin portions may be embedded in the through-substrate via.

According to an embodiment of the disclosure, in the semiconductor structure, the through-substrate via may not contact the plurality of annular portions.

According to an embodiment of the disclosure, in the semiconductor structure, a plurality of top-view patterns of the plurality of end portions may be U-shaped and have a plurality of openings. The plurality of openings may face different directions.

According to an embodiment of the disclosure, in the semiconductor structure, a top-view pattern of the through-substrate via may be located in the plurality of openings. The plurality of top-view patterns of the plurality of end portions may include a plurality of overlapping portions overlapping the top-view pattern of the through-substrate via.

According to an embodiment of the disclosure, in the semiconductor structure, the plurality of overlapping portions may be adjacent to bottoms of the plurality of openings.

According to an embodiment of the disclosure, in the semiconductor structure, the plurality of overlapping portions may be embedded in the through-substrate via.

According to an embodiment of the disclosure, in the semiconductor structure, the through-substrate via may have a first end and a second end opposite to each other. A width of the first end may be greater than a width of the second end.

According to an embodiment of the disclosure, the semiconductor structure may further include a first bonding layer and a second bonding layer. The first bonding layer is located on one of two adjacent first wafers. The second bonding layer is located on the other of the two adjacent first wafers. The first bonding layer is bonded to the second bonding layer.

According to an embodiment of the disclosure, the semiconductor structure may further include a second wafer. The plurality of first wafers are stacked on the second wafer. A bottommost first wafer may be bonded to the second wafer.

According to an embodiment of the disclosure, the semiconductor structure may further include the first bonding layer and the second bonding layer. The first bonding layer is located on the bottommost first wafer. The second bonding layer is located on the second wafer. The first bonding layer may be bonded to the second bonding layer.

According to an embodiment of the disclosure, in the semiconductor structure, the second wafer may include a first side and a second side opposite to each other. The first side may be adjacent to the bottommost first wafer.

According to an embodiment of the disclosure, the semiconductor structure may further include a redistribution layer (RDL). The redistribution layer may be disposed adjacent to the first side. The through-substrate via may be connected to the redistribution layer.

According to an embodiment of the disclosure, the semiconductor structure may further include the redistribution layer. The redistribution layer may be disposed adjacent to the second side. The through-substrate via may be connected to the redistribution layer.

According to an embodiment of the disclosure, the semiconductor structure may further include the redistribution layer. The redistribution layer is on a topmost first wafer. The through-substrate via is connected to the redistribution layer.

According to an embodiment of the disclosure, the semiconductor structure may further include a dielectric layer. The dielectric layer covers the redistribution layer.

According to an embodiment of the disclosure, the semiconductor structure may further include a pad structure. The pad structure is located in the dielectric layer. The pad structure is connected to the redistribution layer.

According to an embodiment of the disclosure, in the semiconductor structure, the dielectric layer may have an opening exposing the pad structure.

Based on the above, in the semiconductor structure provided by the disclosure, the plurality of first wafers include the plurality of conductive connection lines. Each of the conductive connection lines is located in the corresponding first wafer. The through-substrate via passes through the plurality of first wafers and the plurality of end portions of the plurality of conductive connection lines, and the plurality of end portions are embedded in the through-substrate via. In this way, the plurality of first wafers may be effectively electrically connected to each other through the plurality of conductive connection lines and the through-substrate via, thereby preventing an open circuit between the plurality of first wafers and thus preventing the failure of the semiconductor structure.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1 is a top view of a semiconductor structure according to some embodiments of the disclosure.

FIG. 2 is a cross-sectional view along section line I-I′ in FIG. 1.

FIG. 3 is a perspective view of conductive connection lines and a through-substrate via in FIG. 2.

FIG. 4 is a cross-sectional view according to other embodiments of the disclosure.

FIG. 5 is a top view of a semiconductor structure according to other embodiments of the disclosure.

FIG. 6 is a cross-sectional view along section line II-II′ in FIG. 5.

FIG. 7 is a perspective view of conductive connection lines and a through-substrate via in FIG. 6.

FIG. 8 is a cross-sectional view according to other embodiments of the disclosure.

### DESCRIPTION OF THE EMBODIMENTS

The following embodiments will be described in detail with reference to the accompanying drawings, but the provided embodiments are not intended to limit the scope covered by the disclosure. In order to facilitate understanding, the same components will be described with the same reference numerals in the following description. In addition, the drawings are for illustrative purposes only and are not drawn to scale. Additionally, features in the top view, the cross-sectional view, and the perspective view are not drawn to the same scale. In fact, the dimensions of the various features may be arbitrarily increased or reduced for clarity of discussion.

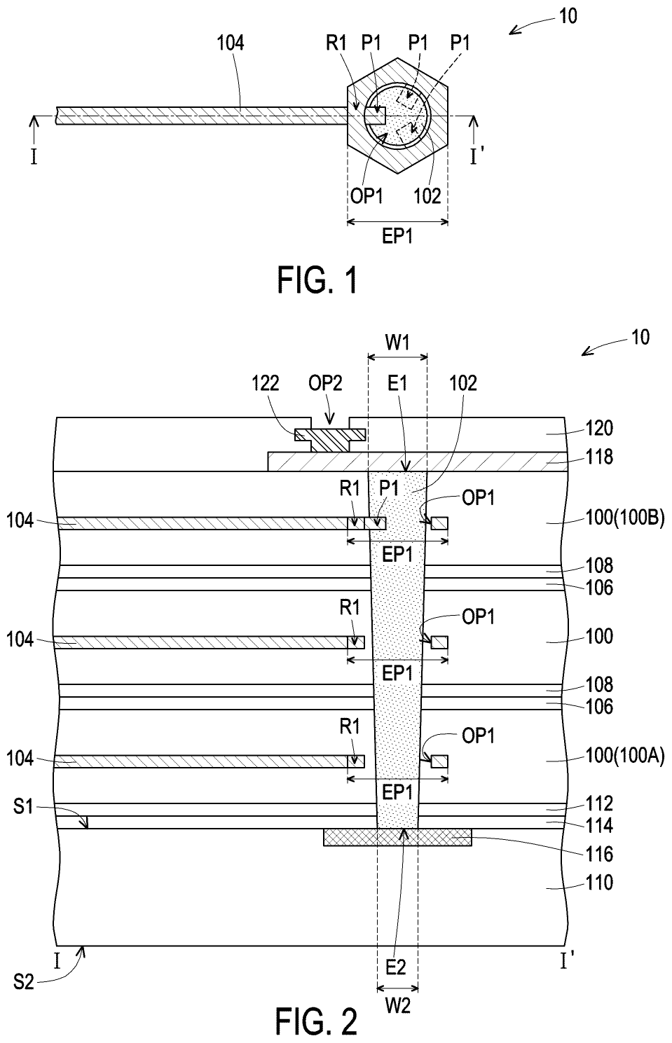

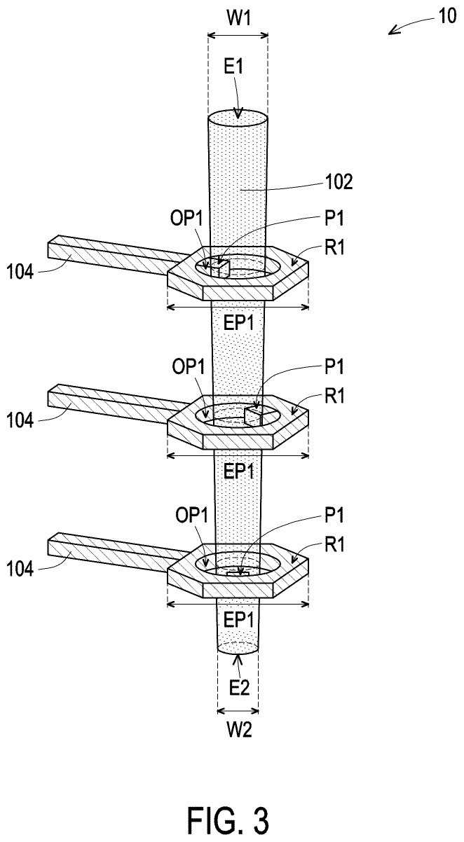

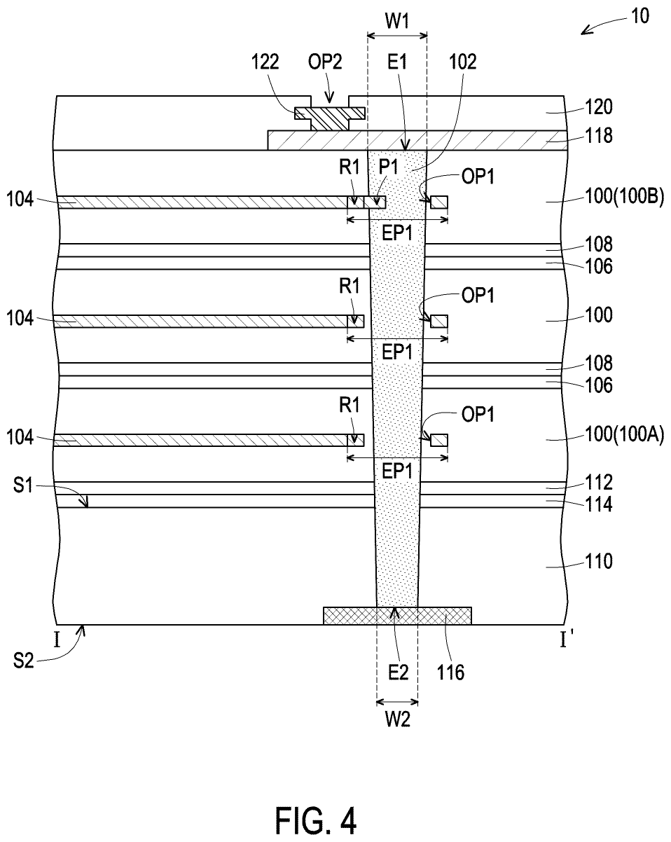

FIG. 1 is a top view of a semiconductor structure according to some embodiments of the disclosure. FIG. 2 is a cross-sectional view along section line I-I′ in FIG. 1. FIG. 3 is a perspective view of conductive connection lines and a through-substrate via in FIG. 2. FIG. 4 is a cross-sectional view according to other embodiments of the disclosure. In FIG. 1 and FIG. 3, some components in FIG. 2 are omitted to clearly illustrate the arrangement relationship between the components in FIG. 1 and FIG. 3.

Referring to FIG. 1 to FIG. 3, a semiconductor structure 10 includes a plurality of wafers 100 and a through-substrate via 102. In some embodiments, the wafer 100 may be a component wafer. The wafer 100 may include required components such as a substrate, a semiconductor device, a dielectric layer, and an interconnection structure, and the description thereof is omitted here. The plurality of wafers 100 include a plurality of conductive connection lines 104. Each of the conductive connection lines 104 is located in the corresponding wafer 100. In some embodiments, the conductive connection line 104 may be an integrally formed structure. The conductive connection line 104 may be a single-layer structure or a multi-layer structure. In some embodiments, a material of the conductive connection line 104 is, for example, copper, aluminum, tungsten, tantalum, tantalum nitride, titanium, titanium nitride, or a combination thereof. In addition, the number of wafers 100 and the number of conductive connection lines 104 are not limited to the numbers in the figures. As long as the number of wafers 100 and the number of conductive connection lines 104 is plural, it falls within the scope of the disclosure.

The through-substrate via 102 passes through the plurality of wafers 100 and a plurality of end portions EP1 of the plurality of conductive connection lines 104. The plurality of end portions EP1 are embedded in the through-substrate via 102. The through-substrate via 102 may be electrically connected to the semiconductor device (not shown) in the wafer 100 through the conductive connection line 104. In this way, the plurality of wafers 100 may be effectively electrically connected to each other through the plurality of conductive connection lines 104 and the through-substrate via 102, thereby preventing an open circuit between the plurality of wafers 100 and thus preventing the failure of the semiconductor structure 10. In some embodiments, the through-substrate via 102 may have a first end E1 and a second end E2 opposite to each other. The first end E1 may be adjacent to a topmost wafer 100B, and the second end E2 may be adjacent to a bottommost wafer 100A. A width W1 of the first end E1 may be greater than a width W2 of the second end E2. The through-substrate via 102 may be a single-layer structure or a multi-layer structure. In some embodiments, a material of the through-substrate via 102 is, for example, copper, tantalum, tantalum nitride, or a combination thereof.

In some embodiments, as shown in FIG. 1 to FIG. 3, the plurality of end portions EP1 may include a plurality of annular portions R1 and a plurality of pin portions P1. Each of the annular portions R1 may have an opening OP1. Each of the pin portions P1 is connected to the corresponding annular portion R1 and protrudes toward an inside of the corresponding opening OP1. A plurality of top-view patterns of the plurality of pin portions P1 may not overlap each other. In some embodiments, the through-substrate via 102 may pass through a plurality of openings OP1. In some embodiments, the plurality of pin portions P1 may be embedded in the through-substrate via 102. In some embodiments, the through-substrate via 102 may not contact the plurality of annular portions R1.

In some embodiments, the semiconductor structure 10 may further include a bonding layer 106 and a bonding layer 108. The bonding layer 106 is located on one of two adjacent wafers 100. The bonding layer 108 is located on the other of the two adjacent wafers 100. The bonding layer 106 is bonded to bonding layer 108. In some embodiments, a material of the bonding layer 106 and a material of the bonding layer 108 are, for example, oxides (e.g., silicon oxides). In some embodiments, the bonding method of the bonding layer 106 and the bonding layer 108 is, for example, a fusion bonding method. When the material of the bonding layer 106 and the material of the bonding layer 108 are oxides (e.g., silicon oxides), the bonding method of the bonding layer 106 and the bonding layer 108 is, for example, an oxide to oxide bonding method.

In some embodiments, the semiconductor structure 10 may further include a wafer 110. The plurality of wafers 100 are stacked on the wafer 110. The wafer 110 may include a first side S1 and a second side S2 opposite to each other. The first side S1 may be adjacent to the bottommost wafer 100A. In some embodiments, the wafer 110 may be a component wafer. The wafer 110 may include required components such as a substrate, a semiconductor device, a dielectric layer, and an interconnection structure, and the description thereof is omitted here. In some embodiments, the bottommost wafer 100A may be bonded to wafer 110. The semiconductor structure 10 may further include a bonding layer 112 and a bonding layer 114. The bonding layer 112 is located on the bottommost wafer 100A. The bonding layer 114 is located on the wafer 110. The bonding layer 112 may be bonded to the bonding layer 114. In some embodiments, a material of the bonding layer 112 and a material of the bonding layer 114 are, for example, oxides (e.g., silicon oxides). In some embodiments, the bonding method of the bonding layer 112 and the bonding layer 114 is, for example, a fusion bonding method. When the material of the bonding layer 112 and the material of the bonding layer 114 are oxides (e.g., silicon oxides), the bonding method of the bonding layer 112 and the bonding layer 114 is, for example, an oxide-to-oxide bonding method.

In some embodiments, the semiconductor structure 10 may further include a redistribution layer 116. In some embodiments, as shown in FIG. 2, the redistribution layer 116 may be disposed adjacent to the first side S1, but the disclosure is not limited thereto. In other embodiments, as shown in FIG. 4, the redistribution layer may be disposed adjacent to the second side S2. The through-substrate via 102 may be connected to the redistribution layer 116. The through-substrate via 102 may be electrically connected to the semiconductor device (not shown) in the wafer 110 through the redistribution layer 116. In this way, the plurality of wafers 100 and the wafer 110 may be electrically connected to each other through the redistribution layer 116 and the through-substrate via 102. In some embodiments, a material of the redistribution layer 116 is, for example, copper, tantalum, tantalum nitride, or a combination thereof.

In some embodiments, the semiconductor structure 10 may further include a redistribution layer 118. The redistribution layer 118 is located on the topmost wafer 100B. The through-substrate via 102 is connected to the redistribution layer 118. In some embodiments, a material of the redistribution layer 118 is, for example, copper, tantalum, tantalum nitride, or a combination thereof.

In some embodiments, the semiconductor structure 10 may further include a dielectric layer 120. The dielectric layer 120 covers the redistribution layer 118. In some embodiments, a material of the dielectric layer 120 is, for example, an oxide (e.g., silicon oxide).

In some embodiments, the semiconductor structure 10 may further include a pad structure 122. The pad structure 122 is located in the dielectric layer 120. The pad structure 122 is connected to the redistribution layer 118. In some embodiments, the dielectric layer 120 may have an opening OP2 exposing the pad structure 122. The pad structure 122 may be a single-layer structure or a multi-layer structure. In some embodiments, a material of the pad structure 122 is, for example, copper, aluminum, tantalum, tantalum nitride, titanium, titanium nitride, or a combination thereof.

Based on the above embodiments, it can be seen that in the semiconductor structure 10, the plurality of wafers 100 include the plurality of conductive connection lines 104. Each of the conductive connection lines 104 is located in the corresponding wafer 100. The through-substrate via 102 passes through the plurality of wafers 100 and the plurality of end portions EP1 of the plurality of conductive connection lines 104, and the plurality of end portions EP1 are embedded in the through-substrate via 102. In this way, the plurality of wafers 100 may be effectively electrically connected to each other through the plurality of conductive connection lines 104 and the through-substrate via 102, thereby preventing an open circuit between the plurality of wafers 100 and thus preventing the failure of the semiconductor structure 10.

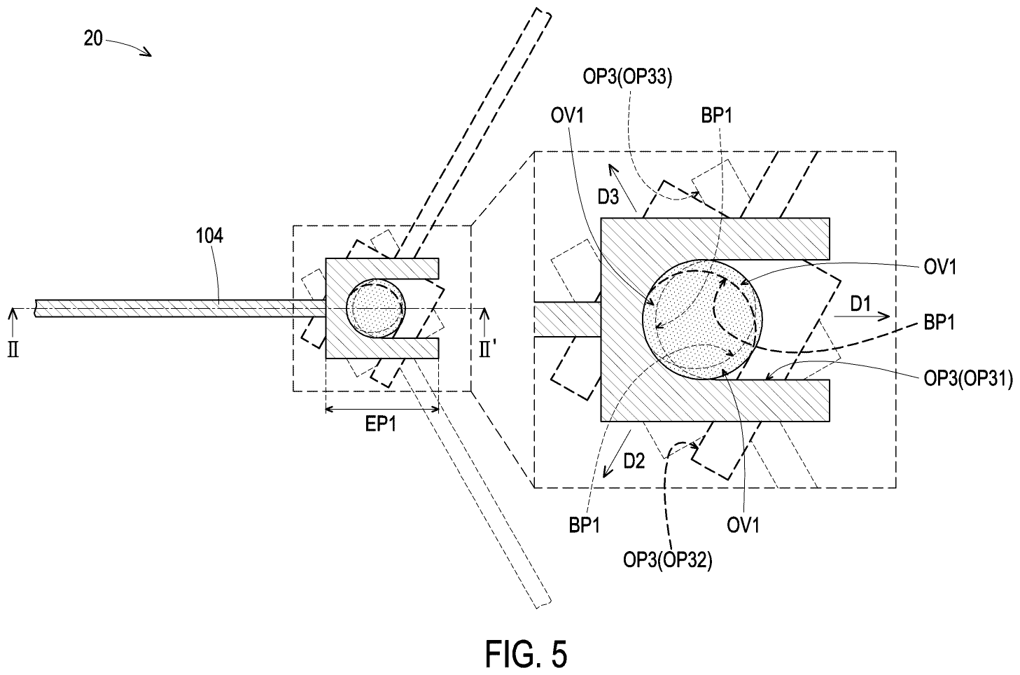

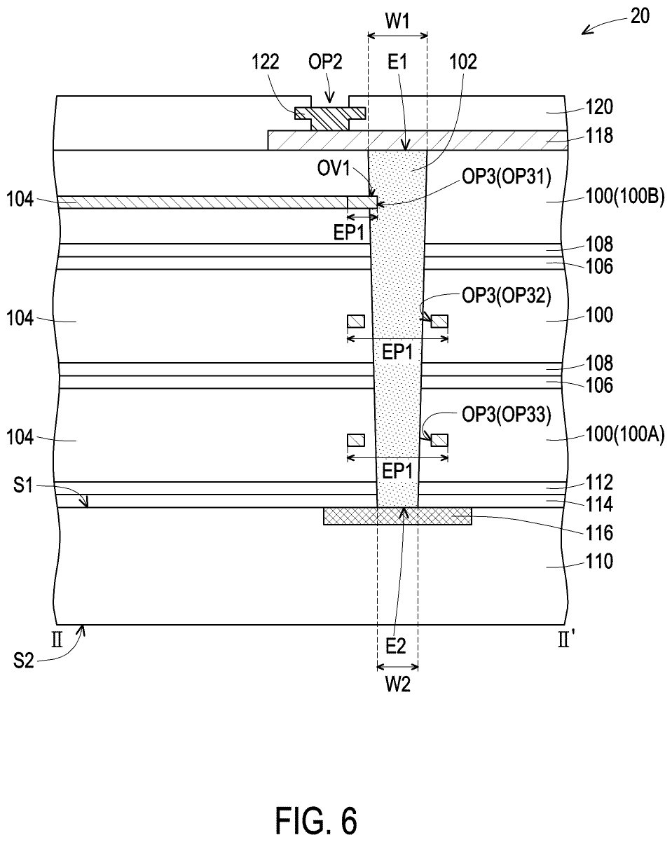

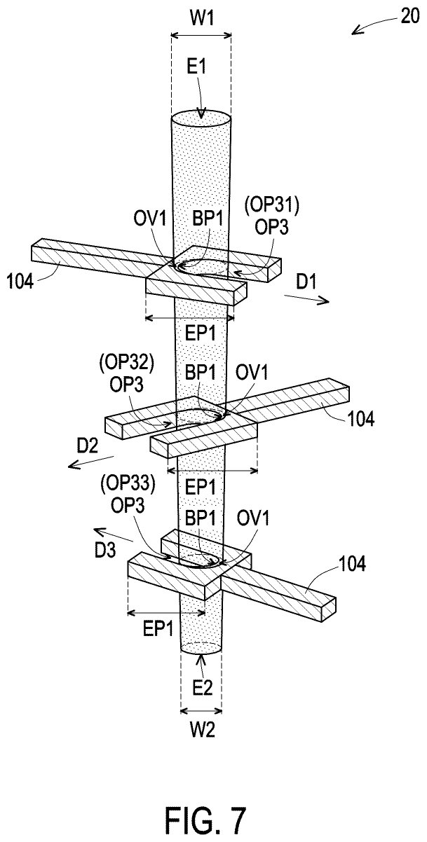

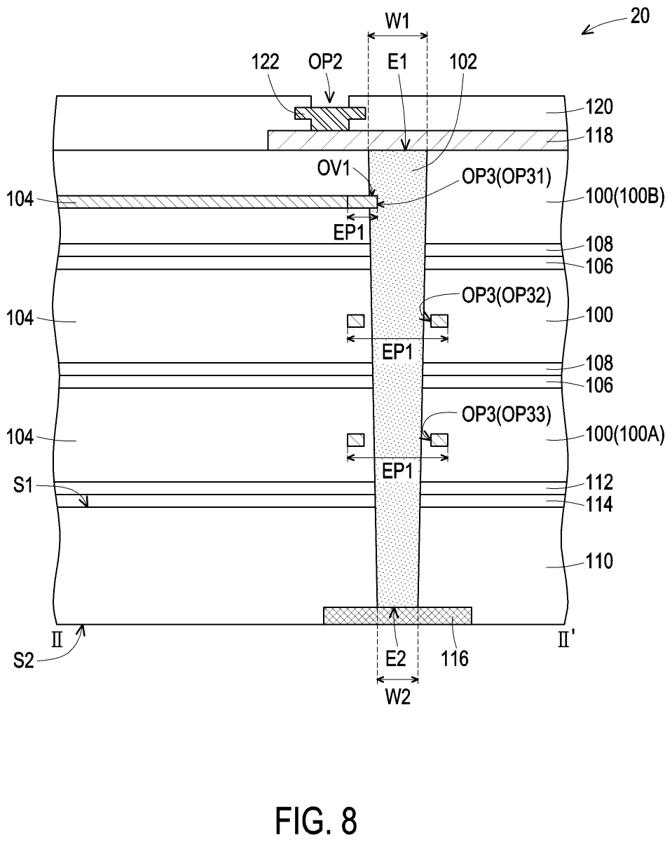

FIG. 5 is a top view of a semiconductor structure according to other embodiments of the disclosure. FIG. 6 is a cross-sectional view along section line II-II′ in FIG. 5. FIG. 7 is a perspective view of conductive connection lines and a through-substrate via in FIG. 6. FIG. 8 is a cross-sectional view according to other embodiments of the disclosure. In FIG. 5 and FIG. 7, some components in FIG. 6 are omitted to clearly illustrate the arrangement relationship between the components in FIG. 5 and FIG. 7.

Referring to FIG. 1 to FIG. 8, the differences between the semiconductor structure 10 of FIG. 1 to FIG. 4 and a semiconductor structure 20 of FIG. 5 to FIG. 8 are as follows. Referring to FIG. 5 to FIG. 8, in the semiconductor structure 20, a plurality of top-view patterns of the plurality of end portions EP1 may be U-shaped and have a plurality of openings OP3. The plurality of openings OP3 may face different directions. For example, an opening OP31 may face a direction D1, an opening OP32 may face a direction D2, and an opening OP33 may face a direction D3. In the semiconductor structure 20, a top-view pattern of the through-substrate via 102 may be located in the plurality of openings OP3. In the semiconductor structure 20, the plurality of top-view patterns of the plurality of end portions EP1 may include a plurality of overlapping portions OV1 overlapping the top-view pattern of the through-substrate via 102. In some embodiments, the plurality of overlapping portions OV1 may be adjacent to bottoms BP1 of the plurality of openings OP3. In some embodiments, the plurality of overlapping portions OV1 may be embedded in the through-substrate via 102. In addition, in FIG. 1 to FIG. 8, the same or similar components are denoted by the same referential numerals, and descriptions thereof are omitted.

Based on the above embodiments, it can be seen that in the semiconductor structure 20, the plurality of wafers 100 include the plurality of conductive connection lines 104. Each of the conductive connection lines 104 is located in the corresponding wafer 100. The through-substrate via 102 passes through the plurality of wafers 100 and the plurality of end portions EP1 of the plurality of conductive connection lines 104, and the plurality of end portions EP1 are embedded in the through-substrate via 102. In this way, the plurality of wafers 100 may be effectively electrically connected to each other through the plurality of conductive connection lines 104 and the through-substrate via 102, thereby preventing an open circuit between the plurality of wafers 100 and thus preventing the failure of the semiconductor structure 20.

To sum up, the semiconductor structure of the above embodiments includes the plurality of first wafers and the through-substrate via. The plurality of first wafers include the plurality of conductive connection lines. Each of the conductive connection lines is located in the corresponding first wafer. The through-substrate via passes through the plurality of first wafers and the plurality of end portions of the plurality of conductive connection lines. The plurality of end portions are embedded in the through-substrate via. In this way, the plurality of first wafers may be effectively electrically connected to each other through the plurality of conductive connection lines and the through-substrate via, thereby preventing an open circuit between the plurality of first wafers and thus preventing the failure of the semiconductor structure.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A semiconductor structure comprising:
a plurality of first wafers, comprising a plurality of conductive connection lines, wherein each of the conductive connection lines is located in the corresponding first wafer; and
a through-substrate via, passing through the plurality of first wafers and a plurality of end portions of the plurality of conductive connection lines, wherein the plurality of end portions are embedded in the through-substrate via.

2. The semiconductor structure according to claim 1, wherein
the plurality of end portions comprise a plurality of annular portions and a plurality of pin portions,
each of the annular portions has an opening,
each of the pin portions is connected to the corresponding annular portion and protrudes toward an inside of the corresponding opening, and
a plurality of top-view patterns of the plurality of pin portions do not overlap each other.

3. The semiconductor structure according to claim 2, wherein the through-substrate via passes through a plurality of openings.

4. The semiconductor structure according to claim 2, wherein the plurality of pin portions are embedded in the through-substrate via.

5. The semiconductor structure according to claim 2, wherein the through-substrate via does not contact the plurality of annular portions.

6. The semiconductor structure according to claim 1, wherein
a plurality of top-view patterns of the plurality of end portions are U-shaped and have a plurality of openings, and
the plurality of openings face different directions.

7. The semiconductor structure according to claim 6, wherein
a top-view pattern of the through-substrate via is located in the plurality of openings, and
the plurality of top-view patterns of the plurality of end portions comprise a plurality of overlapping portions overlapping the top-view pattern of the through-substrate via.

8. The semiconductor structure according to claim 7, wherein the plurality of overlapping portions are adjacent to bottoms of the plurality of openings.

9. The semiconductor structure according to claim 7, wherein the plurality of overlapping portions are embedded in the through-substrate via.

10. The semiconductor structure according to claim 1, wherein the through-substrate via has a first end and a second end opposite to each other, and a width of the first end is greater than a width of the second end.

11. The semiconductor structure according to claim 1, further comprising:
a first bonding layer, located on one of two adjacent first wafers; and
a second bonding layer, located on the other of the two adjacent first wafers, wherein the first bonding layer is bonded to the second bonding layer.

12. The semiconductor structure according to claim 1, further comprising:
a second wafer, wherein the plurality of first wafers are stacked on the second wafer, and a bottommost first wafer is bonded to the second wafer.

13. The semiconductor structure according to claim 12, further comprising:
a first bonding layer, located on the bottommost first wafer; and
a second bonding layer, located on the second wafer, wherein the first bonding layer is bonded to the second bonding layer.

14. The semiconductor structure according to claim 12, wherein the second wafer comprises a first side and a second side opposite to each other, and the first side is adjacent to the bottommost first wafer.

15. The semiconductor structure according to claim 14, further comprising:
a redistribution layer, disposed adjacent to the first side, wherein the through-substrate via is connected to the redistribution layer.

16. The semiconductor structure according to claim 14, further comprising:
a redistribution layer, disposed adjacent to the second side, wherein the through-substrate via is connected to the redistribution layer.

17. The semiconductor structure according to claim 12, further comprising:
a redistribution layer, located on a topmost first wafer, wherein the through-substrate via is connected to the redistribution layer.

18. The semiconductor structure according to claim 17, further comprising:
a dielectric layer, covering the redistribution layer.

19. The semiconductor structure according to claim 18, further comprising:
a pad structure, located in the dielectric layer, and connected to the redistribution layer.

20. The semiconductor structure according to claim 19, wherein the dielectric layer has an opening exposing the pad structure.
